(19) United States
(12) Patent Application Publication
(10) Pub. No.: US 2001/0027449 A1
(43) Pub. Date: Oct. 4, 2001

(54) Instantaneous internet charging

(76) Inventor: Carl A. Wright, Saline, MI (US)

Correspondence Address: John G. Posa, Gifford, Krass, Groh, Sprinkle, Anderson & Citkowski, P.C., 280 N. Old Woodward Ave., Suite 400, Birmingham, MI, 48009, US

(21) Appl. No.: 09/767,014

(22) Filed: Jan. 22, 2001

Related U.S. Application Data
(60) Provisional application No. 60/177,475, filed on Jan. 21, 2000.

(51) Int. Cl. G01R 11/56; G06F 17/00; G01R 21/133

(52) U.S. Cl. 705/412

(57) ABSTRACT

The present invention is a method and system for providing and displaying on a computer device information related to charges incurred for the consumption of Internet services. Using such a system, a consumer of services is notified of the charges and usage information within seconds of the actual consumption of services, thereby permitting the consumer to budget for services and control their consumption of services accordingly. Preferably, the charge and usage information includes ongoing updates on the basis of the smallest incremental unit consumed, to provide the consumer with a running total of the amount of services used at any one point in time; the charges incurred for such usage; the charges for proposed actions so that the consumer can determine an action's cost in advance; and predictions regarding future usage and expenditures based on the consumer's utilization history.

### REFERENCE TO RELATED APPLICATIONS

This application claims priority of U.S. provisional patent application Ser. No. 60/177,475 filed Jan. 21, 2000, the entire contents of which is incorporated herein by reference.

### FIELD OF THE INVENTION

The present invention relates generally to a method for providing immediate feedback information related to the provision of Internet services. More particularly, the present invention provides near instantaneous presentation of usage, rate, and billing account information related to the consumption of Internet services by one or more users.

### BACKGROUND OF THE INVENTION

Traditionally, a provider of Internet services (ISP) enables access to the Internet via a dialup connection. A consumer of these services generally establishes a communication connection between a computer and the server of the ISP via a modem and a telephone line (dialup connection), and the ISP extends the connection to the Internet and its associated ports. Under this method, the consumer cannot use the telephone line for other services, such as traditional phone calls, for the duration of the communication session.

When the consumer finishes using the Internet service, the consumer invokes computer software to terminate the communications connection between the Internet server and the consumer's computer. The ISP typically bills for the consumed Internet services according to a flat rate plan, without regard to the actual time spent connected to the ISP's server, or based on the actual time spent connected to Internet services beyond any number of contracted hours.

With the inception of permanent (“always-on”) Internet connection service technology, ISPs expanded their service offerings to include constant connection from the consumer's computer to the Internet. The constant communication connection permits continual Internet access without monopolizing the telephone line. Thus, the consumer simultaneously utilizes the telephone line for various telephone-related services while accessing the Internet via the computer.

The current art provides numerous technical methods for constant communication connections. These current methods, however, generally continue to provide the same flat rate billing model associated with dialup connections. The industry typically seeks to employ a usage-based billing architecture wherein the service provider assesses a rate for the actual amount of service consumed online, measured in any units of measure selected by the service provider; calculates a charge according to the assessed rate and the consumed units of measurement; and bills the consumer accordingly. Consumers use the services without knowledge of the total amount owed for the use until well after the fact, resulting in both anticipatory anxiety prior to using services and shock at the amount owed when the bill finally arrives.

What is needed, then, is a billing model for electronic or digital services predicated on immediacy, throughput, and reliability. Under such a billing model, the consumer of services receives immediate notification of information related to the actual consumption of services, thereby permitting the consumer to budget and control spending for services accordingly. Preferably, the billing information includes ongoing updates on the basis of the smallest incremental unit consumed, to provide the consumer with a running total of the amount of services used at any one point in time; the charges incurred for such usage; the charges for proposed actions so that the consumer can determine an action's cost in advance; and predictions regarding future usage and expenditures based on the consumer's utilization history.

### SUMMARY OF THE INVENTION

The present invention addresses the shortcomings of the current art to provide instantaneous usage and billing information to a user of Internet or other electronic and digital services. Preferably, the method includes the steps of rating the metered service usage in real time, forwarding the rating information to a destination device, and displaying the information according to the consumer's preference. The information includes the usage, the billing rate for the usage, and the charges incurred for the usage (real-time billing).

Typically, a consumer utilizes a computer system such as a personal computer (PC) to access the Internet. A provider of Internet service or other services (hereafter, ISP) mediates the service, acting as a portal for the PC to the Internet via a communication channel. As the consumer utilizes the service, the ISP meters usage, and provides data relating to the metered usage (i.e. IPDR or TAP3 records) to a provider of instantaneous Internet charging services (hereafter, the IICSP). The ISP, via a server, transmits the data to a server associated with the IICSP, typically utilizing a communication link such as the Internet.

Once the IICSP server receives data relating to the metered usage of services, the IICSP server, via its associated software (hereafter, the real-time rating component), rates the usage based according to various predetermined processes, and transmits a message to a destination location; e.g., the PC of the consumer. The message includes predetermined information such as the metered usage total, the rating information, and the total amount owed for Internet services consumed. The IICSP server transmits the message via a communication channel such as the Internet in predetermined intervals or on an as-requested basis.

As a matter of primary importance, the IICSP server immediately performs the aforedescribed finctions of rating the received metered usage data and transmitting the information, thus permitting the consumer to know within seconds the amount of service consumption and the charges associated therewith. The IICSP server also provides the rating information to software applications for billing purposes and the like.

The foregoing examples represent several of the embodiments of the present invention; however, one skilled in the art will recognize that the examples in no way limit the invention disclosed herein. The features and advantages of the present invention become apparent from the following detailed description of the invention when read with the accompanying drawings.

### BRIEF DESCRIPTION OF THE DRAWINGS

FIG. 1 is a data flow diagram of a preferred embodiment of the present invention;

FIG. 2 is a flow diagram of the process cycle within the real-time rating component;

FIG. 3 illustrates a sample screen desktop band displaying usage charging;

FIG. 4 illustrates a sample screen desktop band displaying a usage total and remaining usage;

FIG. 5 illustrates a sample screen display activated by cursor positioning;

FIG. 6 illustrates a sample screen display wherein the usage information is contained in a browser display;

FIG. 7 illustrates a sample screen display depicting projected costs and user download options;

FIG. 8 illustrates a sample screen display depicting estimated costs and estimated time remaining during a download of a file;

FIG. 9 illustrates an alternative display of spending information where the usage of services is measured in sessions as might be used with older dial-up Internet services environments;

FIG. 10 illustrates a sample screen displaying charging information on a telephone utilizing wireless application protocol; and

FIG. 11 contains a table illustrating examples of record files, field descriptions, field types, and field sizes.

### DETAILED DESCRIPTION OF THE PREFERRED EMBODIMENT

According to the present invention, the consumer of electronic or digital services such as Internet services receives usage and billing information relating to the services within seconds of consuming those services. The IICSP meters and rates Internet usage, calculates an amount owed for services consumed, and notifies the consumer of the same via the Internet. The system, for example, a combination of hardware, software, and communication components, provides the timely information via the Internet to a computer or device, displays the information, and refreshes the same for the benefit of the consumer or recipient of the timely information.

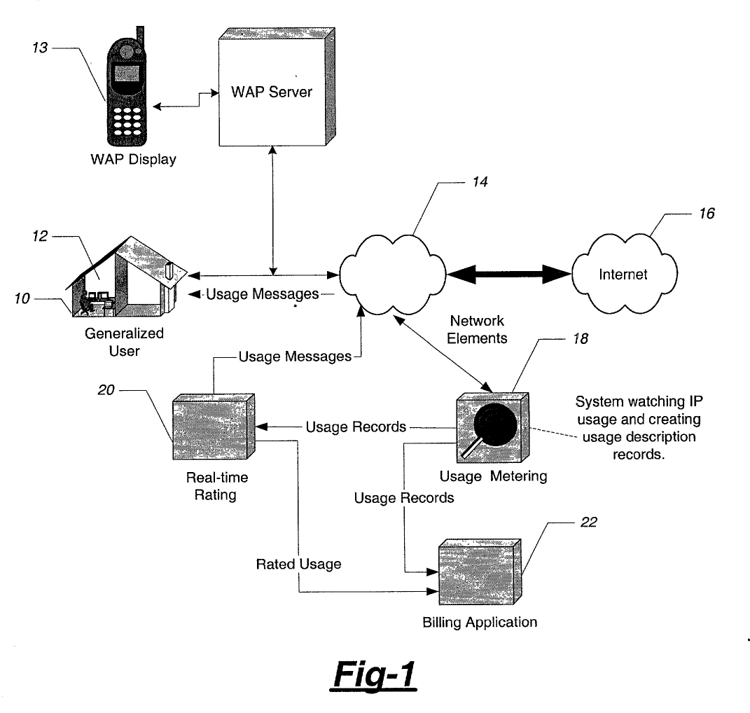

Referring now to the drawings wherein like numbers are used to denote like items throughout, FIG. 1 shows a data flow diagram of the basic flow of data in the invention. A user of Internet services, the consumer 10 utilizes a connection device 12 such as a PC or wireless telephone 13 to access ISP network elements 14. If a wireless telephone 13 or other handheld device is used, various protocol may be employed to facilitate display on the handheld device. The protocol include wireless application protocol (WAP) which utilize a WAP server to mediate transmissions between the WAP handheld device and the ISP network elements 14. The ISP network elements 14 function as a portal into the Internet, and initiates usage of the Internet services for the consumer. According to a predetermined plan, the ISP network elements 14 provide a communication conduit from the connection device 12 to the Internet 16, thus effecting communication services between the connection device 12 and various devices or networks, for example, a website server. The physical and logical communication link between the consumer's connection device 12 and the ISP network elements 14 includes software, hardware, or a combination thereof. For example, the connection device 12 accesses the ISP network elements 14 via a Digital Subscriber Line (DSL) connection.

The ISP measures usage of the ISP service and creates usage description records via a metering device 18. Typically, the metering device 18 includes network components involved in the provision of services for the consumer; e.g., routers, servers, and software. The metering device 18 collects various data related to the provision of services. These data generally include information directly relating to the units of service used (hereafter, units consumed). The units of measure include time, event, or functional units as predetermined by the service provider; e.g., the wireless service provider, the Application Service Provider (ASP), or the ISP. For example, the units of measure include minutes of service, megabytes of data, transactions processed, images shown, and pages of data.

Once the metering device 18 collects the data, the metering devices measures or determines the units of service consumed, and incorporates the total units of consumed data into the usage description record. As the metering device 18 meters the units and creates the usage description records (hereafter, the usage records), the metering device 18 forwards the usage records related to the measured units to both a rating device 20 and any other billing application 22 and its associated devices (hereafter, the billing application 22).

The rating device 20, associated with the IICSP, prices or values (rates) the service provided to the consumer. The rates are derived from a rating plan determined by other means, usually on a rate per unit of measure basis. Preferably, the rating device 20 receives and rates each unit within a relatively short time after consumption. The rating device includes any hardware, software, or other component capable of carrying out the function described herein; e.g., a computer having software that provides real-time rating functionality. In various embodiments, a single component such as a server incorporates both the metering device 18 and the rating device 20.

Once the rating device 20 provides the rate for the metered units, the rating device 20 transfers information pertaining to the rate and usage (hereafter, usage message) via a communication link to a predetermined location, such as the connection device 12 used by the consumer. The usage message contains, for example, a service description, additional descriptive text, total units consumed, unit of measure, rate per unit of measure, cost for a consumption event, a user bill period-to-date spending total, and an account bill period-to-date spending total. The consumption event information generally relates to a specific online event such as a file transfer from one location to another. The rating device 20 maintains ongoing totals of spending for each consumer and updates those totals with each new spending event.

The communication link used to transport the usage message from the rating device 20 includes private networks, public networks such as the Internet, wireless communications channels of the electromagnetic energy spectrum, or other means. For example, the rating device 20 transmits the usage message to the ISP network elements 14 via the Internet. The ISP network elements 14, in turn, forward the usage message to the PC 12 of the user 10 via the always-on connection.

A software component residing on the PC (hereafter, the PC software component) receives the usage message, and displays its content on the display device of the PC. The PC software component also contains the functionality necessary to store the usage message, evaluate spending-to-date total against any action requests such as an alarm or pop-up notification panel, execute action requests if permitted, and display various data components in a variety of ways, as hereinafter described.

Preferably, the rating device 20 transfers the usage message nearly instantaneously; i.e., as soon as the rating device 20 receives or calculates the information to be sent. Alternatively, the rating device enables the user to access the information; e.g., storing it on a website server.

In addition, the rating device 20 includes or is associated with an interface to transfer data pertaining to the rated usage to and from the billing application 22. After receiving both the usage records from the metering device 18 and the rated usage data from the rating device 20, the billing application utilizes the received usage records and data to carry out billing functions according to a predetermined plan; e.g., reconciling the usage records with the rated usage data and billing consumers of services. In various embodiments, the billing application 22 receives the rated usage data from the rating device 20, searches and retrieves rate plan information related to the particular subscriber of services consumed, and forwards the rate plan information to the rating device 20.

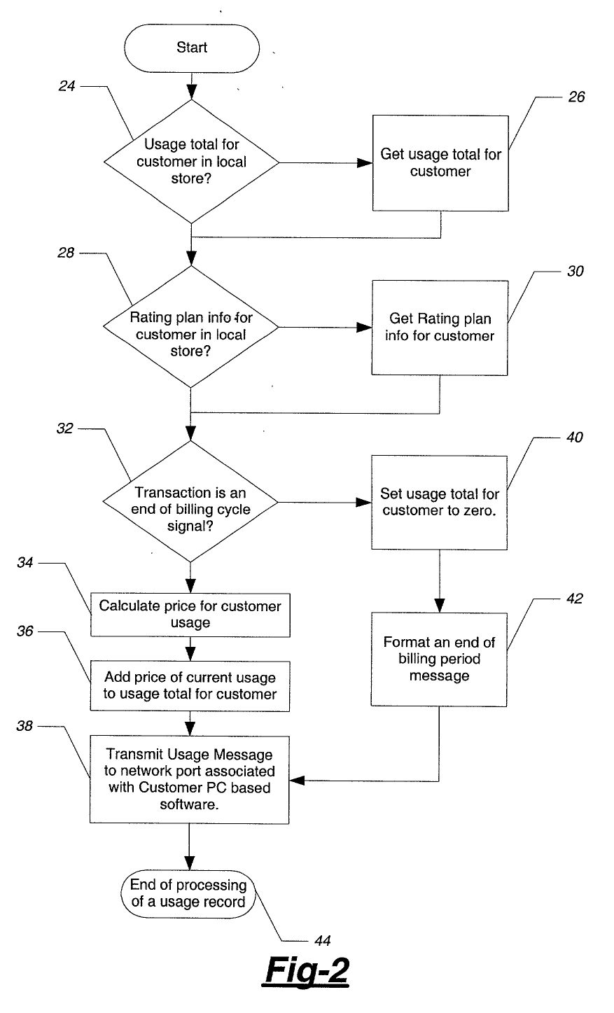

Turning now to FIG. 2, there is shown a flow diagram of the process cycle within the component software that performs real-time rating task. In one embodiment, the real-time rating process contemplates a single PC/single billing account model. In this model, the real-time rating component checks a local store of data for a usage total for a particular consumer 24. If the usage total cannot be found, the real-time rating component solicits the usage total 26 for the consumer from a predetermined source; e.g., the billing application 22. If the usage total is available in the local store, the real-time rating component checks the local store for a rating plan 28 pertinent to the particular consumer. If the rating plan is not available, the real-time rating component retrieves one from a predetermined source 30, such as a billing application component.

Once the real-time rating component secures the rating plan information, the real-ime rating component determines whether the transaction signals the end of a billing cycle 32. If not, the real-time rating component calculates a price for consumption of the services 34, adds the calculated priced to the retrieved usage total for the particular consumer 36, and transmits the usage message to a network port associated with the consumer's PC and its associated software. If the transaction signals the end of the billing cycle, the real-time rating component sets the usage total for the particular consumer to zero 40, formats a message regarding the end of the billing cycle 42, and transmits the usage message and end-of-billing cycle message to the network port associated with the consumer's PC 38. Thereafter, the real-time rating process completes 44.

Variations of the real-time rating process models include (1) Multiple PCs/Single Billing Account with Pooled Usage Reported; (2) Multiple PCs/Single Billing Account with Individual Usage Reported; and (3) Multiple PCs/One Information Recipient/Single Billing Account structures.

The Multiple PCs/Single Billing Account with Pooled Usage contemplates one-to-many personal computers in any given pool, each personal computer having a usage display software program associated therewith. Each personal computer receives all the usage messages for all the personal computers in the pool, and each personal computer sees usage caused by other PCs in the pool.

The Multiple PCs/Single Billing Account with Individual Usage model encompasses an environment with one-to-many personal computers in any given pool, each PC having a usage display software program. Each PC receives all the usage message information for the user's PC, displays the user's specific usage, and the total usage of the pool. The individual PCs in the pool do not see information specific to other individual PCs in the pool.

The Multiple PCs/One Information Recipient/Single Billing Account model also contemplates an environment with one-to-many personal computers in any given pool, wherein only selected PCs have a usage display software program. Only those PCs preordained as budget controllers/management devices receive both the pool total data and the usage data and are able to display it.

With regard to various types of information receivers; i.e., a device designated to receive and display the usage message, various embodiments incorporate a variety of devices. The information receivers include public Internet terminals, wireless Internet access devices such as web phones, wireless Internet accessible portable computers, access by software agents or other automated processes, and representations of human users.

Public Internet terminals receiving the usage message data permit “pay-per-use” type devices to limit usage to monies already deposited or other such financial limitations. The use of wireless Internet accessible web phones and portable computers that display usage messages keep users of mobile technology up-to-date on usage and spending statuses, while access by software agents or representation of human users (proxy) provide a means for persons to manage budget constraints and the like.

One or more embodiments of the present invention display at least a portion of the usage message data on a display device such as a computer terminal via a graphical user interface (GUI) component. The GUI component permits users to set various display configurations and option parameters such as selecting the number of prior usage records to store, reviewing and printing cached usage records, displaying various portions of the usage message information on the desktop band, and other functions related to charging for usage based IP services.

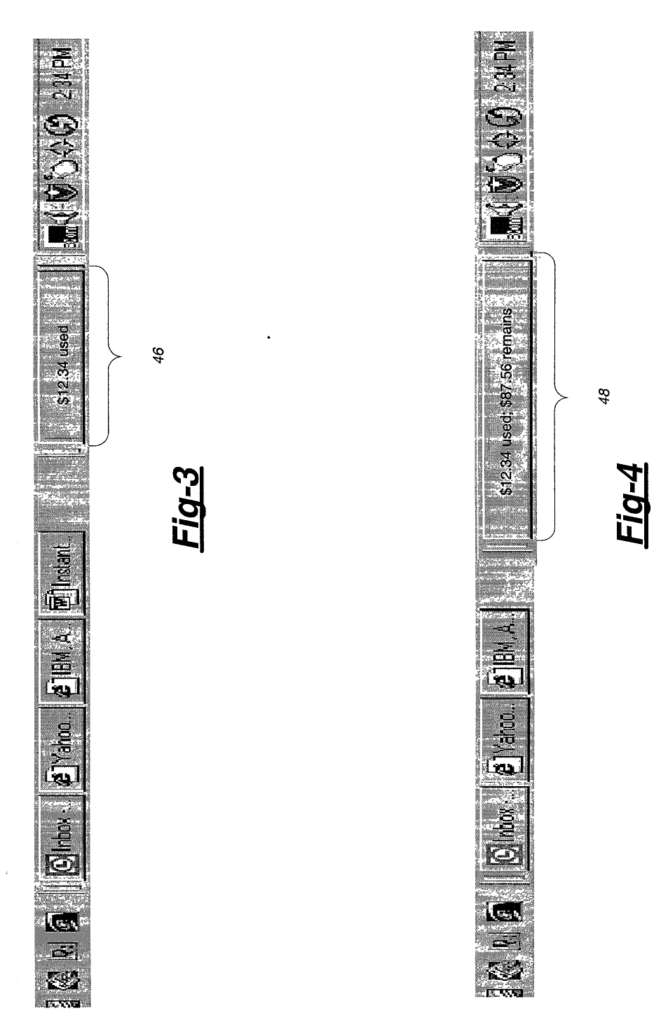

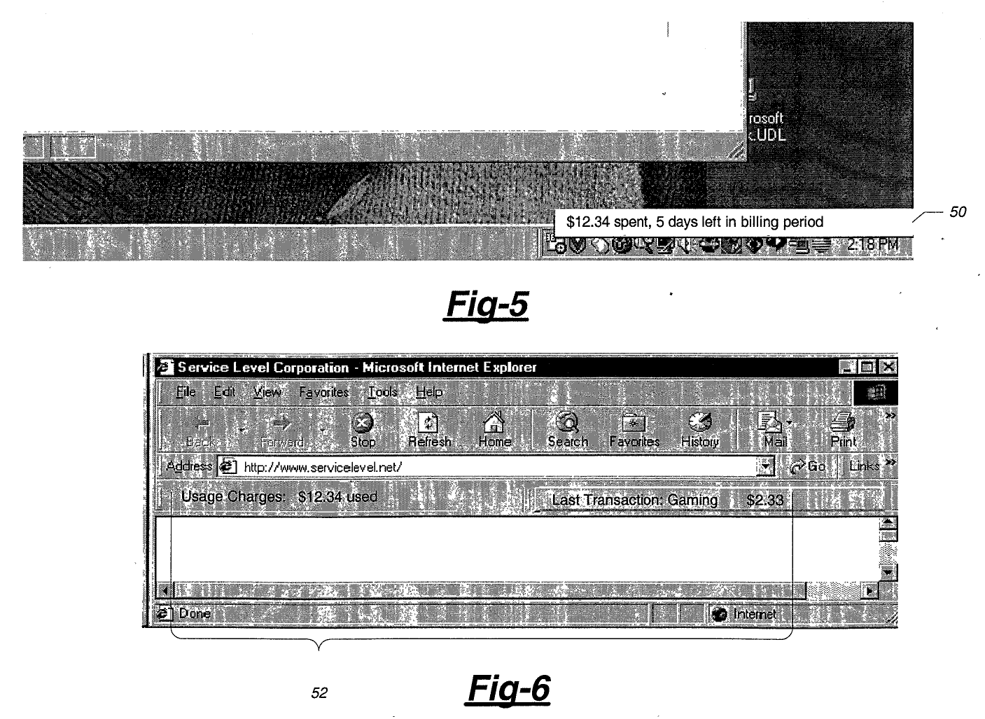

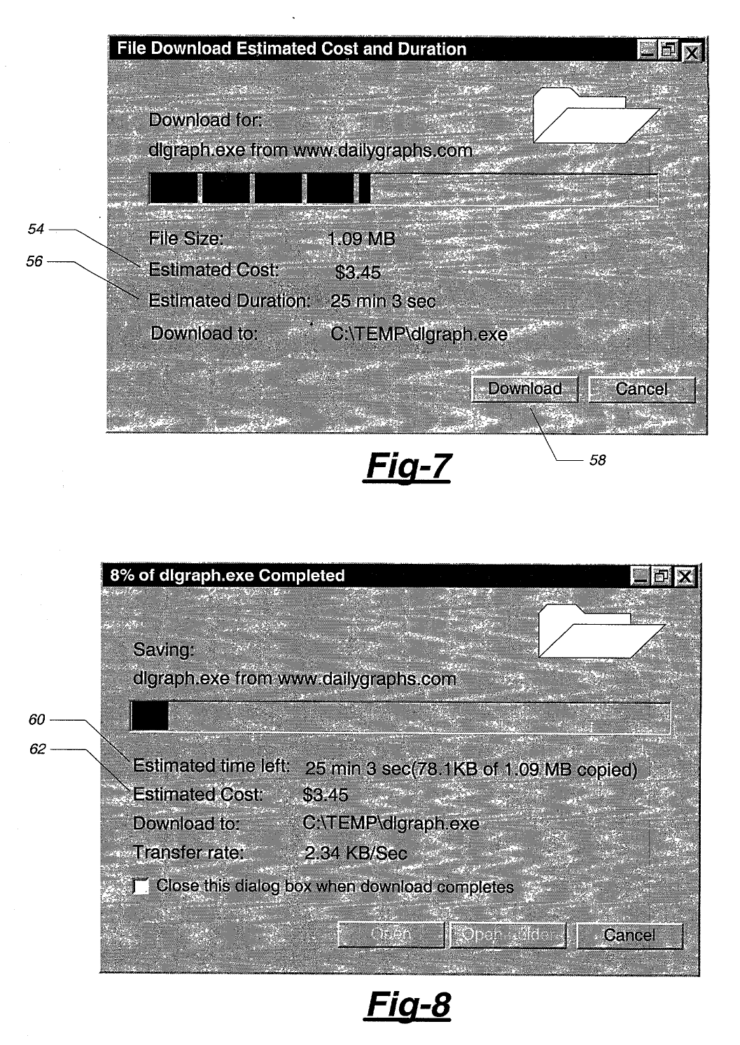

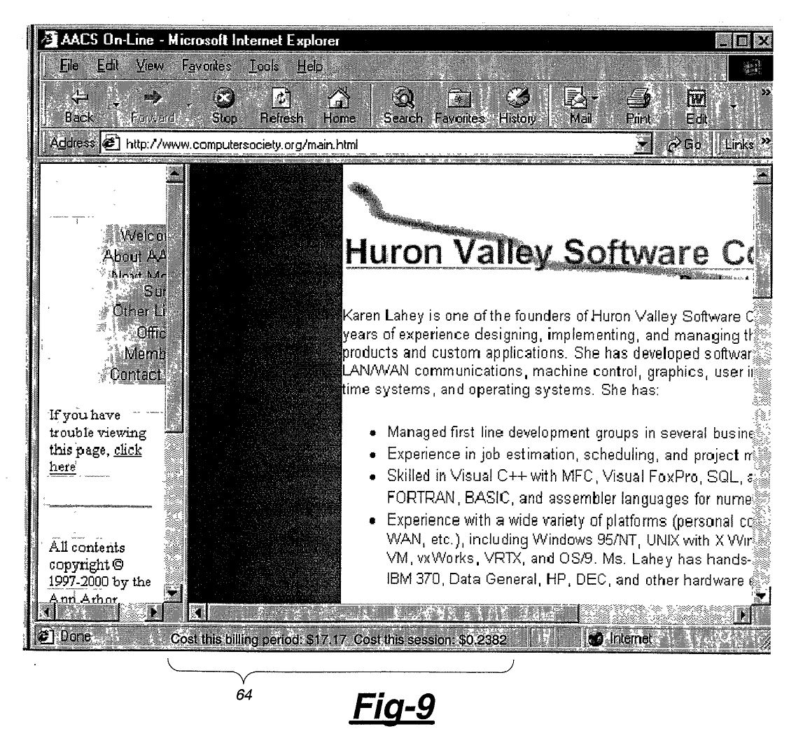

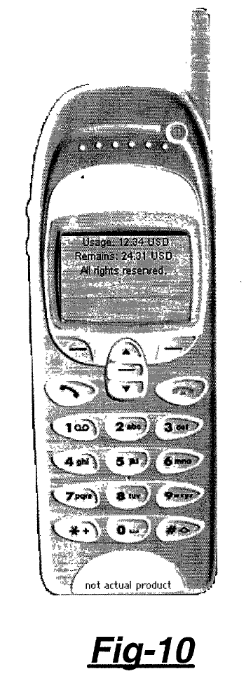

Turning now to FIG. 3, there is shown a sample screen wherein the user desktop band displaying usage charging 46, where the usage charging represents the total amount of charges incurred during the current billing period. FIG. 4 illustrates a sample screen desktop band displaying a usage total and remaining usage 48, where a software component calculates the remaining usage on a pre-existing credit or debit account; i.e., an account established by credit, debit, or other means wherein the account includes a finite amount of funds allocated to future services usage. FIG. 5 illustrates a sample screen desktop band wherein the window containing the charging information 50 activates if the user passes a cursor over an icon associated with software performing the display function. FIG. 6 illustrates a further variation of display options wherein a software module interacts with browser software to display current usage information; e.g., the usage charges and description information 52. FIG. 7 illustrates a sample screen display depicting projected costs 54 as well as the estimated amount of time to download 56 a file, and offers the user an option to download 58, if desired. Similar to the display in the previous figure, FIG. 8 illustrates a sample screen displaying information during the actual download of a file. The sample screen shows the estimated time left to complete the download of a file 60 and the estimated cost if the download completes 62. FIG. 9 illustrates an alternative display of spending information where the usage of services is measured in sessions as might be used with older dial-up Internet services environments. A sample display on a WAP-phone is illustrated in FIG. 10.

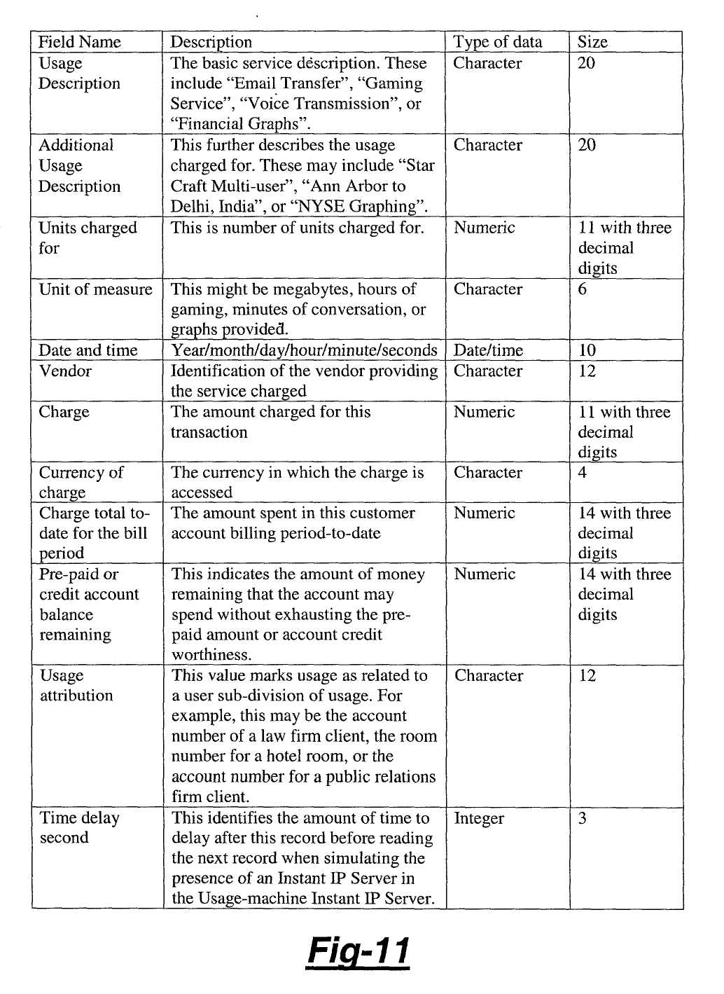

It is further contemplated that various formats may be employed for record implementation. For example, and as illustrated in FIG. 11, the record may contain a variety of fields containing various data.

As one skilled in the art will appreciate, the invention disclosed herein contemplates embodiments and modifications, including the following. In one embodiment, the IICSP acts as financial intermediary between the consumer and a service provider by including one or more software components to effect payment charging and collection. For example, the PC software component gathers credit or debit card information from the consumer and submits the same to the proper payment processing centers to process the charge at the end of the billing period for the consumer.

In another embodiment, the real-time rating component or other software provides instantaneous discounts/rebates on charges incurred. For example, if the consumer visits websites offering promotional packages, website-related software tracks the visit and interacts with the real-time rating component via an Internet connection to pass the earned discount/rebate information. The real-time rating component reconciles the earned discount/rebate information and the charging information to accord the consumer the discounted rate, discounted charges or rebate.

Yet another embodiment permits usage categorization or segregation. One or more software components accept a signal from a consumer and mark all transactions received after a certain point in time to segregate billing. For example, a law firm segregates usage of services by client to enable passing along the usage charge to the appropriate client. The lawyer using this embodiment takes action via the software components to distinguish among clients, and the software aggregates the usage information accordingly. Variations in the application of this invention also include billing folios of hotel clients, hospital patients and so forth.

A further embodiment subdivides usage according to the consumer's view. To accomplish this, a rating device, the metering device, or both accept a signal indicating a subdivision request, and subdivide the usage and rate data accordingly.

The foregoing examples represent several of the embodiments of the present invention; however, one skilled in the art will recognize that the invention described herein may be implemented in a variety of ways. Therefore, the present invention is defined only by the claims hereafter, and not limited in scope by the preceding examples.

I claim:

1. A method for providing information related to metered usage of an electronic or digital service consumed by a user, the method comprising the steps of:
receiving data relating to the metered usage of the consumed service;
rating the metered usage based on the received data;
generating information based on the rated metered usage; and
providing the information via a communication link to a destination location within a close time proximity to the actual consumption of the service.

2. The method of claim 1, further comprising a final step of providing the information to a billing application.

3. The method of claim 1, further comprising a final step of displaying the information on a display device.

4. The method of claim 3, wherein the display device further comprises a wireless communication device.

5. The method of claim 3, wherein the display device further comprises a computer.

6. The method of claim 1, wherein the step of generating information further comprises continuously updating the information as the units of service are consumed.

7. The method of claim 1, wherein the generated information further comprises an amount owed for consumed service such that the amount owed relates to the metered consumed units and the assessed rate.

8. The method of claim 1, wherein the generated information further comprises a quote related to consumption of service.

9. The method of claim 1, further comprising a step of providing a message notifying a user of an event.

10. A method for providing timely information related to usage of an Internet service, the method comprising the steps of:
providing measured units of Internet service to one or more users;
tallying the measured units of Internet service provided to one or more users as the measured units of Internet service are consumed by one or more users;
assessing a rate per measured unit of Internet service consumed by one or more users as the measured units are tallied;
calculating a price associated with the consumed measured units of Internet service by multiplying the tally of measured units of Internet service with the assessed rate; and
forwarding, within a close time proximity to the consumption of the measured units of Internet service by one or more users, information via a communication link to a designated location, where the information includes at least one of the tally of the measured unit of Internet service, the assessed rated, and the calculated price.

11. The method according to claim 10, further comprising an initial step of accessing, by one or more users, a connection device connected to the Internet.

12. The method according to claim 11, wherein the connection device further comprises a display device.

13. The method according to claim 12, wherein the display device further comprises a telephone.

14. The method according to claim 13, wherein the telephone utilizes wireless technology.

15. The method according to claim 11, further comprising a final step of displaying the forwarded information on the display device accessed by the user.

16. The method according to claim 10, wherein the forwarded information further comprises the tally, the assessed rate, and the calculated price associated with the consumed measured units of Internet service.

17. The method according to claim 10, wherein the communication link further comprises the Internet.

18. The method according to claim 10, further comprising the step of purchasing the Internet service prior to providing measured units of Internet service to one or more users.

19. The method according to claim 18, wherein the forwarded information further comprises data relating to the purchased Internet service not yet consumed.

20. The method according to claim 10, wherein the forwarded information further comprising identification of one or more of the users of the Internet services.

21. The method according to claim 10, further comprising a step of estimating an expense associated with a particular Internet service prior to consumption of the particular Internet service.

22. The method according to claim 10, further comprising a step of requesting payment of the calculated price for consumed Internet services.

23. The method according to claim 10, further comprising a step of collecting the calculated price for consumed Internet services.

24. The method according to claim 10, further comprising a step of discounting the calculated price according to a predetermined criterion.
